(19) United States
(12) Patent Application Publication
(10) Pub. No.: US 2006/0154152 A1
(43) Pub. Date: Jul. 13, 2006

(54) Flare reduction in photolithography

(75) Inventor: Manish Chandhok, Beaverton, OR (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 11/032,712

(22) Filed: Jan. 10, 2005

(51) Int. Cl. G03C 5/00; G03F 1/00; G21K 5/00

(52) U.S. Cl. 430/5; 430/322; 430/323; 430/324; 378/35

(57) ABSTRACT

Lithography masks that include sub-resolution features to reduce flare are disclosed and described herein.

### BACKGROUND OF THE INVENTION

1. Field of the Invention

Embodiments of the present invention relate to the field of integrated circuit manufacturing. More specifically, embodiments of the present invention relate to photolithography tools and processes.

2. Background Information

In the current state of integrated circuit manufacturing a process known as photolithography is typically used in order to form circuitry features onto substrates such as silicon wafers. A photolithography process typically involves several operations including, for example, an exposure operation whereby a photoresist layer on a wafer is exposed to electromagnetic radiation that is reflected or transmitted through a patterned mask and through one or more lens. The patterned mask may be either a transmissive or reflective type of mask depending upon, for example, the wavelength of the exposure radiation.

In recent years, the circuitry features being formed on these substrates have become increasingly smaller and smaller. As circuitry features become smaller, the wavelengths of the electromagnetic radiation used during the exposure operation have likewise become smaller. Currently, deep ultraviolet (DUV) and extreme ultraviolet (EUV) radiation are being investigated for use in photolithography processes. These types of electromagnetic radiation are at the far end of the electromagnetic spectrum with wavelengths of less than 200 nanometers (nm). For example, in the case of DUV, 193 nm and in the case of EUV, 13.5 nm.

One problem currently being encountered in photolithography processes is the presence of flare in the electromagnetic radiation that irradiates the photoresist film on the wafer surface. Flare may be viewed as scattered light (or electromagnetic radiation). Flare has at least two negative impacts relative to photolithography processes. First, when flare occurs, the desired shadows created by the patterned mask become blurred with lower contrast resulting in poor imprinting of the photoresist film. Second, when flare occurs, the process window is reduced. A process window can be defined by two parameters, depth of focus (DOF) and exposure or dosage latitude. These problems may be a more significant problem as circuitry features become smaller.

The first parameter, DOF, relates to the latitude or allowed range of distances that the wafer may be located from the optical best focus of the (e.g., lithography) system during the exposure process. For example, when the exposure process is using DUV exposure, the DOF may have a range as small as 0.25 microns. The second parameter, exposure or dosage latitude relates to the variation allowed in the amount of time that the wafer (e.g., photoresist film) can be exposed without making the critical dimensions of the features being formed too small or too large. For example, when exposure time is too long, the lines being formed may become too small to meet design criteria.

It has been found that flare may be caused by in-homogeneities, contamination, and/or roughness of the lens/mirrors that are employed in the lithography system. In some optical or lithography systems, such defects or irregularities may cause a greater than 3 percent flare.

### BRIEF DESCRIPTION OF DRAWINGS

The present invention will be described by way of exemplary embodiments, but not limitations, illustrated in the accompanying drawings in which like references denote similar elements, and in which:

FIG. 1 illustrates a system in accordance with some embodiments; and

FIG. 2 illustrates two geometric features and sub-resolution features in accordance with some embodiments.

### DETAILED DESCRIPTION OF THE INVENTION

In the following description, for purposes of explanation, numerous details are set forth in order to provide a thorough understanding of the disclosed embodiments of the present invention. However, it will be apparent to one skilled in the art that these specific details are not required in order to practice the disclosed embodiments of the present invention. In other instances, well-known electrical structures and circuits are shown in block diagram form in order not to obscure the disclosed embodiments of the present invention.

According to various embodiments of the invention, sub-resolution features may be employed in an optical or lithography system in order to reduce flare. The sub-resolution features may be deployed on patterned masks used in the optical or lithography system, which may further be used in, for example, the exposure operation of a photolithography process. The presence of flare, in some instances, may reduce manufacturing yields and reduce the process window. By including sub-resolution features of particular sizes and shapes and locating the sub-resolution features at specific locations on the patterned mask, flare may be reduced. By reducing flare, sharper images may be imprinted onto the surface of the wafer resulting in greater manufacturing yields. The reduction in flare may also mean that the process window may be improved thus resulting in greater process flexibility.

As described herein, sub-resolution features may be features that are much smaller than the main or geometric features that are to be printed using the lithography system. That is, the main or geometric features are the absorption features that make up a pattern on a patterned mask. In contrast, the sub-resolution features, in various embodiments, may be smaller than the minimum feature size that can be resolved by the lithography system, thus they may be called “sub-resolution.” Even though these features may not be resolved, their diffracted orders may scatter off the mask and interact with the neighboring features (e.g., main features). The result is that flare may be reduced producing sharper imprinting on the wafer.

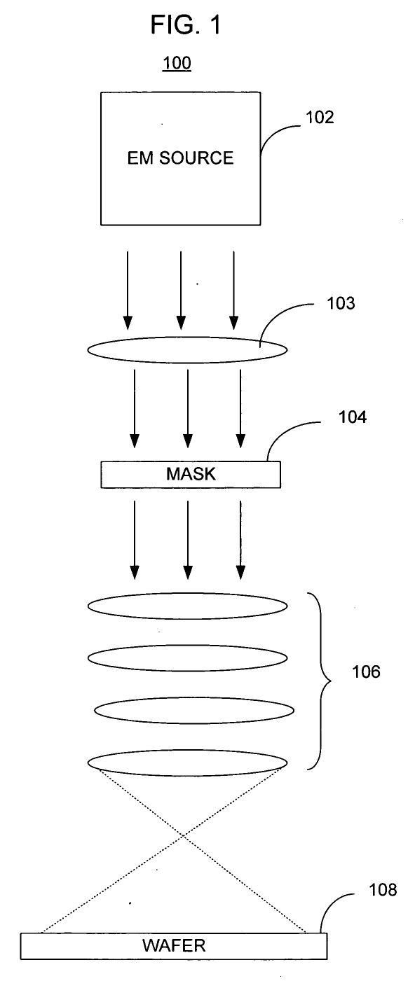

FIG. 1 depicts a system such as a lithography system that may be used in a lithography process in accordance with some embodiments. For the embodiments, the system 100 may include an electromagnetic radiation source 102, a lens 103, a lithography mask 104, and one or more lenses 106. The system 100 may be employed to expose or irradiate a substrate such as a wafer 108 to electromagnetic radiation.

In brief, the electromagnetic radiation source 102 may generate electromagnetic (EM) radiation, which may be transmitted through lens 103 and to the lithography mask 104. The lithography mask 104 may be a transmissive type of mask that includes EM absorption features that make up a pattern disposed on the lithography mask 104. Alternatively, in other embodiments, the lithography mask 104 may be a reflective type of patterned mask that includes absorption features and reflective layers for reflecting the EM radiation. For example, when the lithography process calls for EUV exposure (13.5 nm radiation), the lithography mask may be a reflective type of mask. Regardless of whether the mask is a transmissive or reflective type of mask, the EM radiation that is transmitted through or reflected off of the lithography mask is then transmitted through one or more lenses 106 and onto the wafer 108.

The lithography mask 104 may include an absorption pattern that is further comprised of one or more absorption or geometric features. These geometric features may result in the formation of shadows on the surface of the wafer when the lithography system 100 is employed during the exposure operation of a photolithography process. In addition to the geometric features located on the lithography mask 104, the lithography mask 104 may include sub-resolution features, which may reduce the generation of flare. The mask pattern and the sub-resolution features will be described in greater detail below. In various embodiments, the lithography mask 104 may be adapted to receive electromagnetic radiation having wavelengths less than 248 nm. In some embodiments, the lithography mask 104 may be adapted to receive DUV and/or EUV radiation.

The lens 106 may take the electromagnetic radiation transmitted via the lithography mask 104 and focus the EM radiation onto the surface of the wafer 108. In various embodiments, the EM radiation may have wavelengths between 11 and 365 nm. In some embodiments, the EM radiation focused onto the wafer may be EM radiation at the lower end of the EM spectrum such as DUV and EUV.

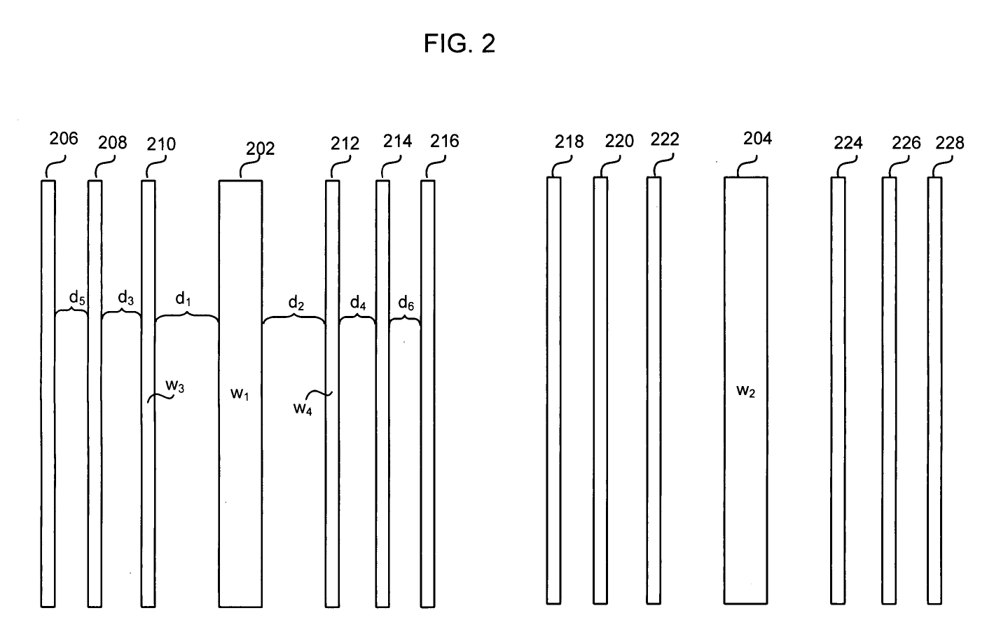

FIG. 2 depicts a plan view of a first and a second geometric feature and a plurality of sub-resolution features on the lithography mask of FIG. 1 in accordance with various embodiments. In the illustration, the first and second geometric feature 202 and 204 may be absorption features that make up a pattern on a lithography mask used during an exposure process. In some instances, the first and second geometric features 202 and 204 may be used to form specific circuitry features on a wafer. For instance, these features may be used to form, for example, conductive interconnects such as metal traces on the wafer. The geometric features 202 and 204 may be made of chrome or some other EM absorbing material. The first and second geometric features 202 and 204 may have predefined widths w₁ and w₂. The first and second geometric features 202 and 204 may be spaced apart on the mask such that there is sufficient space between the two geometric features 202 and 204 to accommodate one or more sub-resolution features. On both sides of the first geometric feature 202 are a first and a second sub-resolution features 210 and 212 that are located at distances d₁ and d₂ from the first geometric feature 202. In some embodiments, the distances d₁ and d₂, may be from about 1.5 times the width (w₁) to about 2 times the width (w₁) of the first geometric feature 202. Further, for these embodiments, the widths (W₃ and w₄) of the first and second sub-resolution features 210 and 212 may be equal to about 0.25 to about 0.50 of the width (w₁) of the first geometric feature 202. For example, in one embodiment, W₃ and w₄ may be equal to about one-third of the width (w₁) of the first geometric feature 202.

The first geometric feature 202 may further be surrounded on the outer sides of the first and second sub-resolution features 210 and 212 by a third, fourth, fifth and sixth sub-resolution features 206, 208, 214, and 216, respectively. The third, fourth, fifth, and sixth sub-resolution features 206, 208, 214, and 216 are spaced apart by distances d₃, d₄, d₅, and d₆. In various embodiments, d₁ is greater than or equal to d₃, and d₃ is greater than or equal to d₅. Similarly, d₂ is greater than or equal to d₃, and d₃ is greater than or equal to d₅. Although each of the two geometric features 202 and 204 are surrounded by three sub-resolution features (206 to 228) on both sides of the geometric features 202 and 204, in other embodiments, less than or more than three sub-resolution features may be placed on the two or more sides of geometric features.

In various embodiments, a greater reduction in flare may be obtained by placing more sub-resolution features on the sides of geometric features. For example, if four sub-resolution features were placed on the opposite sides of the geometric features 202 and 204 instead of three sub-resolution features as depicted in FIG. 2, then better flare reduction may be obtained. However, the addition of each additional sub-resolution features may have diminishing benefit. For example, the placing of the first two sub-resolution features (e.g., sub-resolution features 210 and 212) on the opposite sides of a geometric feature (e.g., 202) may have the biggest impact on flare reduction. The placement of additional sub-resolution features (e.g., sub-resolution features 206, 208, 214, and 216) may result in diminishing benefits in terms of flare reduction. In various embodiments, the sub-resolution features 206 to 228 may be made of the same material (e.g., EM absorption material) that comprises the geometric features 202 and 204.

In specific embodiments, flare in lithography systems may be significantly reduced when sub-resolution features are added to a lithography mask. For these embodiments, the addition of sub-resolution features may result in reducing flare from about 10 to about 50 percent. For example, in some embodiments, the flare generated by a lithography system was reduced by at least 20 percent when sub-resolution features were included in the patterned mask. In the same embodiments, the process window was also increased. For example, the exposure latitude improved from 2.708 to 7.963 while the DOF increased from 0.188 to about 1.88, a tenfold improvement.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the embodiments of the present invention. Therefore, it is manifestly intended that embodiments of this invention be limited only by the claims.

What is claimed is:

1. A lithography mask, comprising:
a geometric feature; and
a first sub-resolution feature located at a first distance from the geometric feature, the first sub-resolution feature or its location is adapted to reduce flare.

2. The lithography mask of claim 1, wherein the mask is adapted to receive electromagnetic radiation having wavelengths less than or equal to 248 nanometers.

3. The lithography mask of claim 1, wherein the first sub-resolution feature is adapted to contribute to reducing flare by at least 10 percent.

4. The lithography mask of claim 1, wherein the first sub-resolution feature is adapted to contribute in increasing a process window by a magnitude of at least five times.

5. The lithography mask of claim 1, wherein the geometric feature has a width (w1) and the first sub-resolution feature has a width (w2) equal to about 0.25 to about 0.50 of the width (w1) of the geometric feature.

6. The lithography mask of claim 1, wherein the geometric feature has a width and said first distance is equal to about 1.5 to about 2.0 times the width of the geometric feature.

7. The lithography mask of claim 1, wherein the mask further includes a second sub-resolution feature, and said geometric feature has a first side and a second side, the first side being opposite of the second side, the first sub-resolution feature is located at the first distance away from the first side and the second sub-resolution feature is located at a second distance away from the second side.

8. The lithography mask of claim 7, wherein the geometric feature has a width and said second sub-resolution feature has a width equal to about 0.5 to about 0.25 of the width of the geometric feature.

9. The lithography mask of claim 7, wherein the geometric feature has a width and said second distance is equal to about 1.5 to about 2.0 times the width of the geometric feature.

10. The lithography mask of claim 7, wherein the mask further comprises a third sub-resolution feature, the third sub-resolution feature is located at a third distance away from the first sub-resolution feature on the opposite side of the first sub-resolution feature from the geometric feature.

11. The lithography mask of claim 10, wherein said third distance is less than the first distance.

12. The lithography mask of claim 3, wherein the lithography mask is adapted to receive electromagnetic radiation.

13. In a lithography system, a method of operation, comprising:
generating electromagnetic radiation;
adapting the electromagnetic radiation to reduce flare; and
irradiating a substrate with the adapted electromagnetic radiation.

14. The method of claim 13, wherein said adapting comprises transmitting through or reflecting the electromagnetic radiation off of a lithography mask comprising sub-resolution feature(s).

15. The method of claim 13, wherein said generating comprises generating electromagnetic radiation having wavelengths of less than or equal to 248 nanometers (nm).

16. The method of claim 13, wherein said irradiating comprises transmitting the adapted electromagnetic radiation through a lens.

17. The method of claim 13, wherein said adapting comprises adapting the electromagnetic radiation to reduce flare by at least 10 percent.

18. A lithography mask, comprising:
a geometric feature; and
a sub-resolution feature located at a selected distance from the geometric feature to reduce flare scattered off a substrate being patterned using the lithography mask.

19. The lithography mask of claim 18, wherein the geometric feature has a width and said selected distance is equal to about 1.5 to about 2.0 times the width of the geometric feature.

20. The lithography mask of claim 18, wherein the selected distance contribute to reducing flare by at least 10 percent

21. The lithography mask of claim 18, wherein the lithography mask adapted to receive electromagnetic radiation having wavelengths less than 193 nanometers.

22. A lithography mask, comprising:
a geometric feature; and
a sub-resolution feature sized to reduce flare scattered off a substrate being patterned using the lithography mask.

23. The lithography mask of claim 22, wherein the geometric feature has a width (w1) and the sub-resolution feature has a width (w2) equal to about 0.25 to about 0.50 of the width (w1) of the geometric feature.

24. The lithography mask of claim 22, wherein the sub-resolution feature is sized to contribute to reducing flare by at least 10 percent.

25. The lithography mask of claim 22, wherein the lithography mask adapted to receive electromagnetic radiation having wavelengths less than or equal to 248 nanometers (nm).
